(19) United States
(12) Patent Application Publication
(10) Pub. No.: US 2026/0332029 A1
(43) Pub. Date: Oct. 22, 2026

(54) GATE DRIVE CIRCUIT FOR A POWER INVERTER LEG IN A POWER INVERTER, POWER INVERTER AND METHODS OF OPERATION THEREOF

(71) Applicants: NANYANG TECHNOLOGICAL UNIVERSITY, Singapore (SG); THE UNIVERSITY OF MANCHESTER, Greater Manchester (GB)

(72) Inventors: Cheng ZHANG, Greater Manchester (GB); Shu Yuen Ron HUI, Singapore (SG)

(21) Appl. No.: 18/996,676

(22) PCT Filed: Jul. 17, 2023
(86) PCT No.: PCT/SG2023/050501

§ 371 Date: Jan. 17, 2025

(30) Foreign Application Priority Data
Jul. 18, 2022 (SG) 10202250496N

(51) Int. Cl. H02M 1/00; H02M 7/5387; H03K 17/13; H03K 17/284

(52) U.S. Cl. CPC H02M 1/0058; H02M 7/53878; H03K 17/133; H03K 17/284; H02M 1/0051

(57) ABSTRACT

A gate drive circuit for a power inverter leg in a power inverter comprises a first power switch with a first reverse conduction channel and a second power switch with a second reverse conduction channel. The gate drive circuit comprises a first gate drive sub-circuit for controlling switching of the first power switch and a second gate drive sub-circuit for controlling switching of the second power switch. The gate drive circuit controls switching of the first and second power switches in a complementary manner, and based on gate drive input signals to the first and second gate drive sub-circuits, the gate drive input signals being indicative of conduction conditions of the first and second reverse conduction channels and a slope of load current in an inductive-resistive load.

### TECHNICAL FIELD

The invention relates generally to the field of power electronics. One aspect of the invention relates to a gate drive circuit for a power inverter leg in a power inverter. Another aspect of the invention relates to a power inverter comprising the gate drive circuit. Another aspect of the invention relates to a method of operating a gate drive circuit for a power inverter leg in a power inverter.

One aspect of the invention has particular, but not exclusive, application for soft switching of a power inverter with operating frequencies up to tens of Mega-Hertz. The invention may have use in wireless power transfer applications.

One aspect of the invention has particular application in reducing power loss in the power inverter. For instance, use of the techniques disclosed herein may enable improved soft-switching of the power switches in the power inverter. Use of the techniques disclosed herein may allow for improved zero-voltage switching (ZVS) to be achieved in one or more of the power switches of the power inverter.

### BACKGROUND

The availability of wide band-gap devices, wireless power transfer (WPT) technology and high-performance magnetic materials has prompted researchers and engineers to explore power converters with operating frequency beyond tens of Mega-Hertz. High-frequency operation not only reduces the size of magnetic components in general power conversion applications, but also increases the quality factor of magnetic coils that are commonly used in WPT applications. Power conversion typically involves dc-dc, dc-ac, ac-ac and ac-dc power conversion. Dc-ac power converter is also known as power inverter. In this document, power converter is used as the general term to cover the power converter family.

Traditional power converters used for switched mode power supplies are operated at a frequency in the typical range of 100 kHz to 500 kHz. For dc-ac power converters used in WPT for example, there is an increasing trend to explore the use of power inverter switching at several industrial, scientific and medical (ISM) frequencies such as 6.78 MHz, 13.56 MHz, 26.96 MHz and 40.66 MHz. Therefore, the operating frequency of some emerging power conversion applications is expected to range from several hundred kilo-Hertz to over 100 MHz as reported in the review paper [Reference: D. J. Perreault, J. Hu, J. M. Rivas, Y. Han, O. Leitermann, R. C. N. Pilawa-Podgurski, A. Sagneri and C. R. Sullivan, “Opportunities and challenges in very high frequency power conversion,” IEEE Applied Power Electronics Conference and Exposition Washington, DC, 2009]. Regardless of the topologies, all switched-mode power converter utilises the fundamental circuit element that chops dc waveforms into ac. soft-switching techniques are essential in this frequency range, among which two are mostly seen in practical applications: the single-switch type class-E or class-φ2 and the half-bridge based (push-pull) class-D/DE [Reference: N. O. Sokal and A. D. Sokal, “Class E-a new class of high-efficiency tuned single-ended switching power amplifiers,” IEEE Journal of Solid-State Circuits, vol. 10, no. 3, pp. 168-176, 1975.].

During the transition of turning on and off the switches, the conductive channel takes a linear transition over a finite time period, as illustrated in FIG. 1. It results in a linear resistive transition for the voltage and current as well and eventually contributed to an overlapped interval that dissipates a switching power loss, shown in FIG. 2. Such a switching power loss is proportional to the switching frequency of the power switch and could become a limiting factor for the switching frequency of the power switch. Soft switching can be achieved by zero-voltage switching (ZVS) or zero-current switching (ZCS). By keeping either the voltage across or current in the power switch to zero, the instantaneous power loss becomes zero. In one example, if a capacitor is connected in shunt to the switch device, quasi-ZVS takes place automatically during the turn-off transition, as shown in FIG. 3. The voltage across the switch rises slower and the I-V integral (which is the energy lost during the transition) is significantly reduced. It is known as a turn-off snubber. However, simply having this shunt capacitor will increase the switching power loss during the turn-on transition, as the energy stored in the capacitor will be completely dissipated on the switch. Therefore, an additional arrangement must be applied to mitigate the turn-on transition.

It should be noted that there are parasitic capacitances in a power electronics switch. FIG. 4 shows a typical electrical equivalent circuit of a power MOSFET with three terminals, namely Gate, Drain and Source. The equivalent output capacitance Coss of the power MOSFET is equal to the sum of the drain-source capacitance (Cds) and gate-drain capacitance (Cgd). The charging and discharging of the switch's output capacitance Coss will contribute to the switching power loss of the power switch.

For WBG devices, the turn-off time is short enough and it can be almost treated as ZVS turn-off by default as the Coss forms a natural turn-off snubber.

For the very-high-frequency applications such as WPT systems, the transmitter side requires an inverter circuit which normally consists of a push-pull circuit—either a half-bridge or a full-bridge power inverter (also as pointed out in Reference: W. D. Braun and D. J. Perreault, “A High-Frequency Inverter for Variable-Load Operation,” IEEE Journal of Emerging and Selected Topics in Power Electronics, vol. 7, no. 2, pp. 706-721, 2019.). There are power switches with their sources connected to floating nets in such circuits and therefore, conventionally, signal isolators and floating power supplies are required to drive these switches. In their work, they have used microcontrollers to generate PWM signals for both top and bottom switches and drive through a pair of identical gate drive circuits with the same latency times.

Regardless of the topologies, all switched-mode power converters utilize the fundamental circuit elements that convert dc voltage or current waveforms into ac ones. Soft-switching techniques are essential in this frequency range, among which two are mostly seen in practical applications: the single-switch type class-E or class-$2 and the half-bridge based (push-pull) class-D/DE (FIG. 5). For the half-bridge-based converters, the gate drive circuit for the top switch requires a floating voltage rail referenced to the mid-point of the inverter leg, which is also known as the switching-node. FIGS. 6a to 6c show some existing examples of gate drive technologies for the top and bottom switches in a power inverter leg. FIG. 6a shows Bootstrap floating gate drive for the top switch by charging a capacitor when the bottom switch is turned on. Or, to put it another way, FIG. 6a shows a bootstrap gate drive for the top switch in the inverter leg. The dc power supply for the top-switch gate drive is provided by a capacitor which is charged through a fast-recovery diode when the bottom switch is turned on. The floating capability is achieved by the fast-recovery diode, and no isolation is needed in this circuit. In FIG. 6b, this shows the use of an isolation transformer to provide a floating gate drive circuit for the top power switch. Or, to put it another way, FIG. 6b illustrates isolation transformers being used to provide two floating power supplies for the gate drives. FIG. 6c shows the use of transformer isolation transformer with coupled secondary windings to provide isolated and floating gate drives for the switches use. Or, to put it another way, FIG. 6c illustrates use of a transformer with coupled seconding windings to provide the gate drives for the two switches.

With an inductive load connected to a half-bridge-based inverter, it is possible to utilise the residual currents in the inductor to force the anti-parallel body diode of the switches conductive and achieve ZVS at the turn-on transition. [Reference: D. C. Hamill, “Class DE inverters and rectifiers for DC-DC conversion,” in PESC Record. 27th Annual IEEE Power Electronics Specialists Conference, Baveno, Italy, 1996.] However, to keep a converter operate at ZVS states requires extra computation and control over the gate signals according to the load impedance. The switching frequency and duty ratio need to be carefully and constantly tracking the resonance tank parameters and the load variation. [Reference: D. C. Hamill, “Class DE inverters and rectifiers for DC-DC conversion,” in PESC Record. 27th Annual IEEE Power Electronics Specialists Conference, Baveno, Italy, 1996.] This often requires complicated control designs or a narrow range of operational region. [Reference: H. Sekiya, M. Matsuo, H. Koizumi, T. Suetsugu, S. Mori and I. Sasase, “New control method of Class DE inverter-Class DE thinning-out inverter,” in INTELEC-Twentieth International Telecommunications Energy Conference, San Francisco, CA, USA, 1998.] [Reference: W. D. Braun and D. J. Perreault, “A High-Frequency Inverter for Variable-Load Operation,” IEEE Journal of Emerging and Selected Topics in Power Electronics, vol. 7, no. 2, pp. 706-721, 2019.] A special kind of ZVS operation is detecting the voltage and current phases in the circuit and triggering the gate signals automatically including the Mazzilli converter [Reference: D. A. Hapidin, I. Saleh, M. M. Munir and Khairurrijal, “Design and Development of a Series-Configuration Mazzilli Zero Voltage Switching Flyback Converter as a High-Voltage Power Supply for Needleless Electrospinning,” in Engineering Physics International Conference, Bandung, Indonesia, 2016.], the TSOS technique [Reference: A. Namadmalan and J. S. Moghani, “Tunable Self-Oscillating Switching Technique for Current Source Induction Heating Systems,” IEEE Transactions on Industrial Electronics, vol. 61, no. 5, pp. 2556-2563, 2014.], the double modulation technique [Reference: H. Belloumi and F. Kourda, “Double Modulation Technique for a ZVS Self-Oscillating Half-Bridge Inverter,” IEEE Transactions on Power Electronics, vol. 30, no. 4, pp. 1907-1913, 2015.], and low-latency frequency tracking technique [Reference: S.-H. Park, Y.-H. Sohn and G.-H. Cho, “SiC-Based 4 MHz 10 KW ZVS Inverter With Fast Resonance Frequency Tracking Control for High-Density Plasma Generators,” IEEE Transactions on Power Electronics, vol. 35, no. 3, pp. 3266-3275, 2020.]. All these methods utilise magnetic coupling components to sense the current signals and generate the gate signals for the switches. In the direct drive type, the gate drive power directly comes from the current transformer and either some energy will be wasted due to gate voltage protection, or undervoltage will not fully turn on the switches. In the indirect type methods, the gate signals are generated referenced to the ground and need paired isolated gate drivers for both top and bottom switches in the half bridge. This results in extra latency time, normally around several tens of nanoseconds assuming state-of-the-art isolators are used [Reference: Texas Instruments datasheet: “UCC21520 4-A, 6-A, 5.7-kVRMS Isolated Dual-Channel Gate Driver,” 2020.]. Because the circuit is self-triggered, the additional latency limits the minimum cycle period and therefore limits the maximum operating frequency. It is also an issue with small-footprint isolator components that the common-mode transient immunity capability limits the rail voltage and switching frequency. [Reference: V. Semiconductors, “Optocoupler Common Mode Transient Immunity (CMTI)—Theory and Practical Solutions,” 2013] As the turn-on and turn-off signals will be determined by the status of the circuit using the quasi-resonance method, the propagation delay of the string of control and drive circuits becomes critical. At frequency of 10 MHz, a period is 100 ns while the current best signal isolators have some tens of ns propagation delay. It is not a serious issue in a half-bridge or full-bridge power inverter with externally controlled ZVS operation because both top and bottom switches will be delayed for the same amount of time. However, in quasi-resonance operation, these delays will add additional times and restrict the maximum operation frequency as well as the level of power.

Another self-triggering technique often seen in the boost [Reference: C. Zhang and D. J. Perreault, “An optimization approach for high-efficiency high-power-density boost converters,” in IEEE 19th Workshop on Control and Modeling for Power Electronics (COMPEL), Padua, Italy, 2018.] or fly-back converters [Reference: T.-Y. Yang, R.-H. Lu, C.-C. Li, F.-C. Tsao and P.-S. Tsu, “Switching Control Circuit Having A Valley Voltage Detector To Achieve Soft Switching For A Resonant Power Converter”. U.S. Pat. No. 7,426,120 B2, 16 9 2008.] is using comparators to detect the voltage signals across the switch. It has the benefit of low latency (state-of-the-art comparators have less than 5 ns propagation delay) and is suitable for operation frequencies higher than 10 MHz. This technique so far has only been applied on single switch converters.

### SUMMARY

Aspects of the invention are as set out in the independent claims. Some optional features of the invention are defined in the dependent claims.

Implementation of the techniques disclosed herein may provide significant technical advantages. For instance, the techniques disclosed herein can be considered to relate to a self-triggered gate drive system (the input signals to the gate drive (sub) circuits may be derived from operating parameters—voltages and currents—in the power inverter leg components) comprising two gate drive (sub) circuits for driving the two power switches in a complementary manner in a power inverter leg under soft-switching condition, which may be used to generate a high-frequency AC output voltage from an input DC voltage source. In at least one implementation, the technique relates to gate drive (sub) circuits and control, and their incorporation into power inverters with capability of switching up to tens of Mega-Hertz. The control of the gate drive circuit may be based on the detection of the conduction of the reverse conduction channel, for instance, an anti-parallel diode of the power switch, and/or the slope of the current of the load, for instance the polarity of the slope. The proposed techniques can be applied to power switches in the power inverter leg (e.g. when in a totem-pole arrangement) in half-bridge power inverter and can be extended to full-bridge power inverter. The techniques have the advantages of not requiring (i) electrical isolation and level-shifter for the high side gate drive signals of the power inverter leg, and (ii) active and continuous computations of the driving frequency and duty ratio of the gate drive signals to maintain ZVS with load variations. In applications where there is very small delay in the gate signal transmission, this enables the gate drive system to operate at frequency in the range from hundreds of kilo-Hertz to at least tens of Mega-Hertz. The techniques may facilitate inherent operation-safe start-up procedure from the power-on instant of the power inverter. The potential applications of this circuit include at least wireless charging systems, energizing windings in vacuum deposition processes, high energy density and efficiency DC-AC and DC-DC converters.

### BRIEF DESCRIPTION OF THE DRAWINGS

The invention will now be described, by way of example only, and with reference to the accompanying drawings in which:

FIG. 1 is a schematic block diagram illustrating (a lateral structure) of conductive channel states from the fully on to fully off for a MOSFET;

FIG. 2 is a series of voltage, current and power curves plotted against time illustrating switching losses due to the resistive transition during the turn-on and turn-off intervals of the MOSFET device of FIG. 1;

FIG. 3 is a series of views illustrating equivalent circuit diagrams and voltage, current and power curves when there is reduced power loss;

FIG. 4 is a schematic circuit diagram illustrating an electrical equivalent circuit of a known power MOSFET;

FIG. 5 is a schematic circuit diagram of a Class D/DE half-bridge power inverter (with a typical inverter leg comprising a top switch and a bottom switch);

FIG. 6 is a series of electrical diagrams illustrating some existing examples of gate drive technologies for the top and bottom switches in a power inverter leg;

FIG. 7 is an electrical schematic diagram illustrating a first exemplary gate drive circuit for a power inverter leg in a power inverter in accordance with the techniques herein disclosed;

FIG. 8 is an electrical schematic diagram illustrating a circuit for implementing a condition one logic block in the circuit of FIG. 7;

FIG. 9 is an electrical schematic diagram illustrating a first variant of the circuit of FIG. 8;

FIG. 10 is an electrical schematic diagram illustrating a second variant of the circuit of FIG. 8;

FIG. 11 is an electrical schematic diagram illustrating a circuit for implementing a condition two logic block in the circuit of FIG. 7;

FIG. 12 is an electrical schematic diagram illustrating a first variant of the circuit of FIG. 11;

FIG. 13 is an electrical schematic diagram illustrating a second variant of the circuit of FIG. 11;

FIG. 14 is an electrical schematic diagram illustrating a circuit for implementing a condition three logic block in the circuit of FIG. 7;

FIG. 15 is an electrical schematic diagram illustrating a first variant of the circuit of FIG. 14;

FIG. 16 is an electrical schematic diagram illustrating a second variant of the circuit of FIG. 14;

FIG. 17 is an electrical schematic diagram illustrating a circuit for implementing a condition four logic block in the circuit of FIG. 7;

FIG. 18 is an electrical schematic diagram illustrating a variant of the circuit of FIG. 17;

FIG. 19 is an electrical schematic diagram illustrating an exemplary bootstrap circuit;

FIG. 20 is an electrical schematic diagram illustrating a circuit providing a practical example of the techniques disclosed herein;

FIG. 21 is electrical schematic diagram illustrating a variant of the circuit of FIG. 20;

FIG. 22 is electrical schematic diagram illustrating extension of the techniques for use with a full-bridge power inverter;

FIG. 23 is a series of schematic diagrams illustrating the operating states of a half-bridge power inverter implementing the techniques described herein;

FIG. 24 is a series of voltage and current curves plotted against time for an operational cycle of the power inverter leg;

FIG. 25 is an electrical schematic diagram of a full-bridge power inverter driven by the proposed gate drive system, for simulation study;

FIG. 26 is a series of simulated waveforms of the inductor current and the mid-point voltages of the two power inverter legs of the electrical circuit of FIG. 25;

FIG. 27 is a plot of voltage versus current for the atypical switching trajectory of a power switch in the power inverter of FIG. 25;

FIG. 28 is a series of electrical circuit diagrams illustrating an example of a half-bridge power inverter using practical component models;

FIG. 29 is a series of simulated waveforms of the inductor current and the midpoint voltages of the power inverter legs of FIG. 28; and

FIG. 30 is a series of electrical circuit diagrams showing, respectively, further variants of FIG. 11 and FIG. 17.

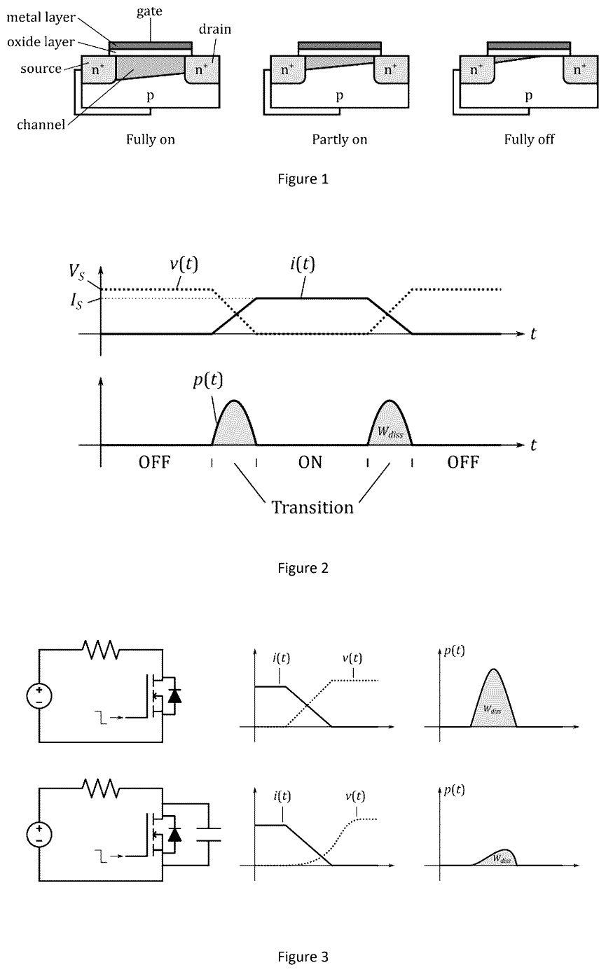

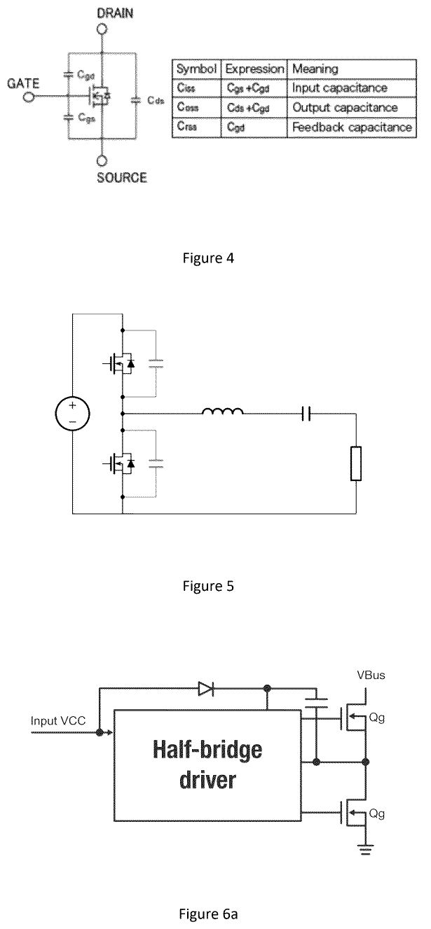

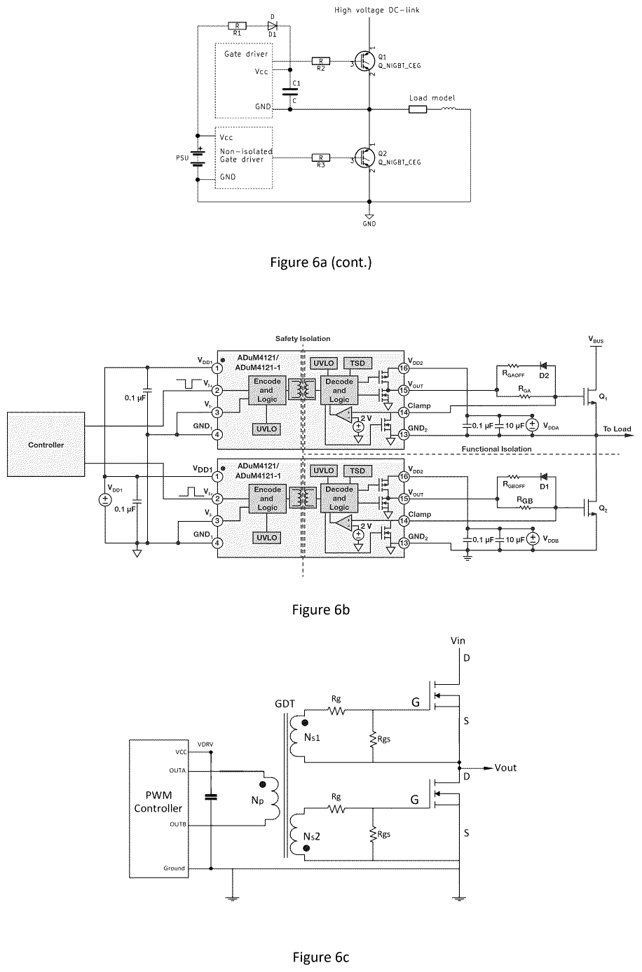

### DETAILED DESCRIPTION

Unless stated otherwise, terms such as “first” and “second” are used to distinguish between the elements such terms describe. Thus, these terms are not necessarily intended to indicate temporal or other prioritisation of such elements.

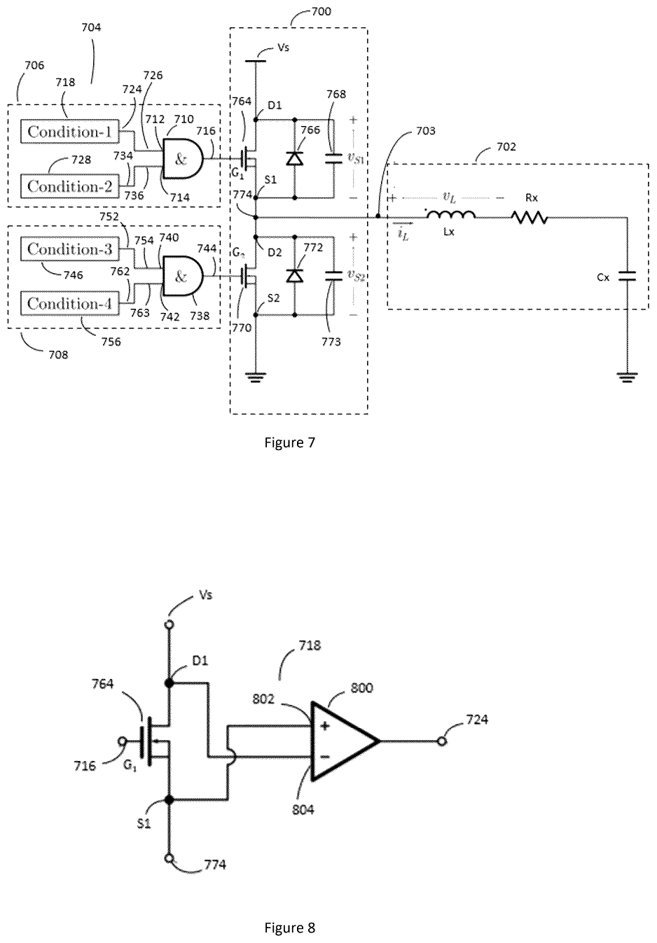

Referring now to FIG. 7, this illustrates power inverter/power inverter leg 700 driving a load 702 from output 703. In the example of FIG. 7, the power inverter 700 comprises a single power inverter leg, a half-bridge power inverter. However, the techniques described in detail below extend to full-bridge power inverters. Further discussion of the power inverter/power inverter leg 700 and the load 702 follows after an initial discussion of first exemplary gate drive circuit 704.

Gate drive circuit 704 comprises a first gate drive sub-circuit 706 and a second gate drive sub-circuit 708.

First gate drive sub-circuit 706 comprises a first AND gate 710 having a first input 712 and a second input 714. First AND gate 710 also has a first AND gate output 716.

First AND gate 710 receives an input on first input 712 from condition one logic block 718 which implements logic condition-1, described in greater detail below. Condition one logic block 718 has a condition one logic block output 724 on which is generated a condition one logic block control signal 726 which, in turn, is first gate drive control signal, the first AND gate first input signal on the first AND gate first input 712.

First AND gate 710 receives an input on second input 714 from condition two logic block 728 which implements logic condition-2, described in greater detail below. Condition two logic block 728 has a condition two logic block output 734 on which is generated a condition two logic block control signal 736 which, in turn, is second gate drive control signal, the first AND gate second input signal on the first AND gate second input 714.

Second gate drive sub-circuit 708 comprises a second AND gate 738 having a first input 740 and a second input 742. Second AND gate 738 also has a second AND gate output 744.

Second AND gate 738 receives an input on first input 740 from condition three logic block 746 which implements logic condition-3, described in greater detail below. Condition three logic block 746 has a condition three logic block output 752 on which is generated a condition three logic block control signal 754 which, in turn, is third gate drive control signal, the second AND gate first input signal on the second AND gate first input 740.

Second AND gate 738 receives an input on second input 742 from condition four logic block 756 which implements logic condition-4, described in greater detail below. Condition four logic block 756 has a condition four logic block output 762 on which is generated a condition four logic block control signal 763 which, in turn, is fourth gate drive control signal, the second AND gate second input signal on the second AND gate second input 742.

Power inverter leg 700 of FIG. 7 comprises a first power switch 764, in this example, a MOSFET, having a first drain terminal D1 connected to the supply power rail Vs, a first gate terminal G1 for receiving—being controlled by—the output signal on the first AND gate output 716 and a first source terminal S1 connected to the midpoint 774 between the switches. First power switch 764 also has an associated first reverse conduction channel, in this example, a first antiparallel diode 766, connected in parallel (anti-parallel) across first power switch 764 between terminals D1 and S1. First power switch 764 also comprises first power switch parasitic capacitance 768 across which voltage Vₛ₁ is developed. Power inverter leg 700 also comprises a second power switch 770, in this example a MOSFET, having a second drain terminal D2 connected to the midpoint 774 between the switches, a second gate terminal G2 for receiving—being controlled by—the output signal on the second AND gate output 744 and a second source terminal S2 connected to ground. Second power switch 770 also has an associated second reverse conduction channel, in this example, a second antiparallel diode 772, connected in parallel across second power switch 770 between terminals D2 and S2. Second power switch 770 also comprises a second power switch parasitic capacitance 773 across which voltage Vs2 is developed.

In the example of FIG. 7, power inverter leg 700 is connected in a totem pole arrangement, with the midpoint 774 between the switches connected to output 703. In this example, source terminal S1 of first power switch 766 is connected through midpoint 774 to the drain terminal D2 of second power switch 770.

Electrical load 702 comprises at least inductor or inductive component Lx across which voltage Vₗ is developed and resistor or resistive component Rx. In the example of FIG. 7, electrical load 702 also has capacitor or capacitive component Cx. Such a load circuit branch is typical in the equivalent circuit for wireless power transfer in which the inductor and capacitor form a resonator. It is used as an example to explain the operation of the proposed gate drive circuit and control. Generally, the techniques herein disclosed are also applicable for a purely inductive-resistive load (a load comprising, effectively, only inductive and resistive components).

It is worth noting that the location of the inductor Lx, the resistor or resistive load Rx and the capacitor(s) or capacitive load Cx in the circuit can be varied without affecting the operation of the techniques herein disclosed. That is, these techniques remain valid if the relative positioning of the impedance components changes.

The gate drive system 704 for a power inverter leg 700 comprises two gate drive circuits 706, 708 respectively, one for controlling the switching state of the first (top) power switch 764 (S₁) and the other for controlling the switching state of the second (bottom) power switch 770 (S₂).

As noted above, the two switches 764 (S₁) and 770 (S₂) in power inverter leg 700 of FIG. 7 are configured in a totem-pole arrangement. In this example, the switches 764, 770 are switched in a complementary manner with a short dead time between their turn-on periods in order to avoid a short-circuit condition. The parasitic output capacitances 768, 773 (i.e. C_{OSS}) of the power switches 764, 770 is zero. This parasitic capacitance 768, 773 provides a zero-voltage conduction for turning off the power switch 764, 770 under ZVS condition inherently. The technical challenge is how to determine the conditions to turn on the power switch under ZVS.

For zero-voltage turn-on of the first (top) power switch 764 (S1) in the inverter leg 700, two conditions are needed as in the following discussion.

### Condition-1: For ZVS Turn on of the Top Switch:

Condition-1 logic block 718 outputs a high logic level signal 726 on condition one logic block output 724 when the equivalent reverse conduction channel (in this example, the anti-parallel body-diode 766) of the first power switch 764 (e.g., top switch) is forced on by the reverse current from the mid-point 774 to the supply voltage rail, and vice versa. In other words, it is triggered by v_{S1}≤0 as shown in FIG. 7. A truth table for Condition-1 is provided in Table I.

TABLE I
Truth table for Condition-1

| Condition | Output |
|---|---|
| v_{S1} ≤ 0 | H |
| v_{S1} > 0 | L |

Thus, it will be appreciated that the gate drive circuit 704 is configured for the first gate drive control signal 726 to indicate when a first reverse conduction channel voltage v_{S1} is less than or equal to zero. In this respect, it is worth noting that the voltage v_{S1} may not be precisely zero in view of the fact that there will always be some voltage drop across the components of the reverse conduction channel, in the example of FIG. 7, the antiparallel diode 766. A typical voltage drop is around typically anywhere between around 0.3V and 1.4 V for a GaN HEMT. The important factor is that the voltage v_{S1} is near zero, effectively zero, (in that it is significantly smaller than the DC rail voltage) sufficient to provide the advantages of zero voltage switching.

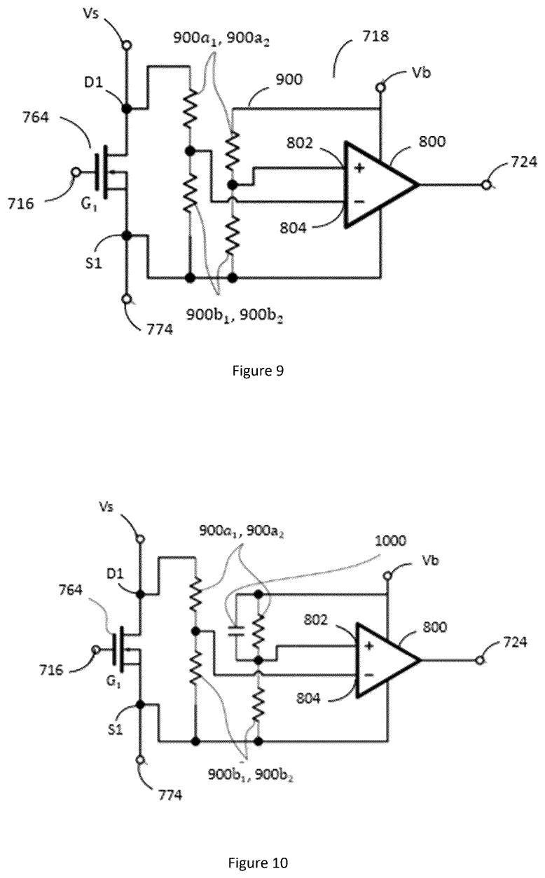

(The level of comparison may be adjusted by the resistors 900a2 and 900b2 (see FIG. 9) as well as affected by the supply Vb, but it is worth nothing that it is a positive voltage, and thus is not related to the maximum negative voltage across the switch. With a small positive voltage set at first comparator first non-inverting input 802 (FIGS. 8 to 10, discussed below), the switch will be turned on when the voltage across D1-S1 drops near zero (e.g. if Vs=100V, this turn-on voltage may be around 1~2V). This is also related to the capacitor 1600 in FIG. 16—to be discussed below—where a startup capacitor is to set the initial voltage at 1304 larger at the starting stage, to help build up ZVS operations.

The minimum voltage set at first comparator first non-inverting input 802 will be zero where it is tied to the mid-point 774 between the first and second power switches, where any negative voltage will be able to trigger turn-on of the switch so there is no limit of maximum negative voltage in this case. At the point of the voltage D1-S1 turns negative the switch will be actively turned-on already.)

Referring to FIG. 8, this condition one logic block 718 can be implemented by a first comparator circuit having a first comparator 800 with first non-inverting input 802 connected to the mid-point 774 between the two switches 764, 770 in the same inverter leg 700, and first inverting input 804 connected to the supply voltage rail Vs. As such, comparator 800 is measuring the voltage Vₛ₁ developed across the first power switch 764, the first antiparallel diode 766 and the first power switch parasitic capacitance 768. That is, the first gate drive control signal is a first output signal of a first comparator 800 having a first non-inverting input 802 connected to a supply voltage rail Vs and a first inverting input 804 connected to a midpoint 774 between the first power switch and the second power switch.

It will be appreciated the first gate drive control signal 726 indicates when a first reverse conduction channel voltage Vₛ₁ is less than or equal to zero.

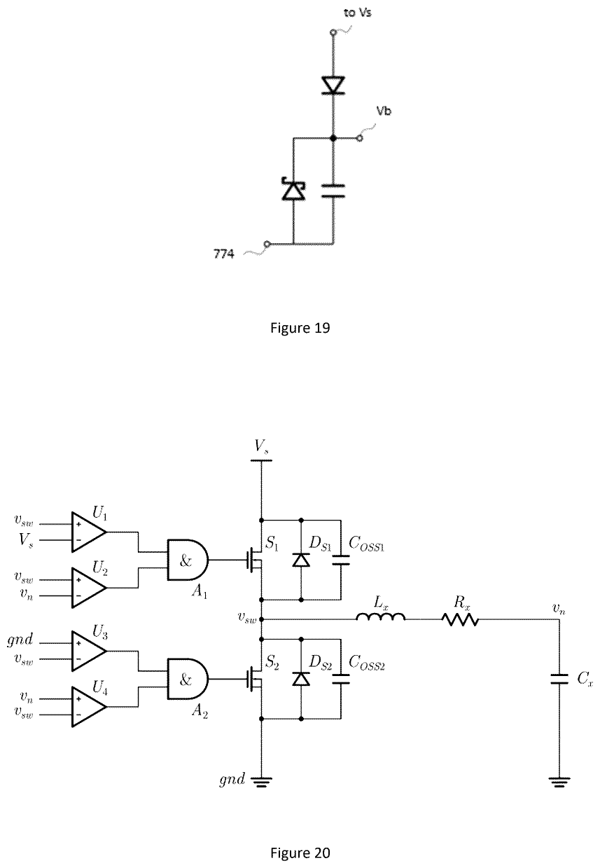

As shown in FIG. 9, a first voltage divider circuit 900 (e.g. a high-speed voltage divider) comprising top resistors 900a1, 900a2 and bottom resistors 900b1, 900b2 may be used to scale the input signals from the source voltage Vs and the midpoint 774 within the acceptable range of the first comparator 800. In the example of FIG. 9, first top resistor 900a1 is connected on a first side thereof to the supply voltage rail Vs and the first power switch first drain terminal D1 and, on the second side thereof, to the first bottom resistor 900b1, at a first side of that, and to the first inverting input 804 of first comparator 800. Second top resistor 900a2 is connected at a first side thereof to the bootstrap supply rail Vb (see FIG. 19) and at a second side thereof to the first non-inverting input 802 of the first comparator 800 and to a first side of second bottom resistor 900b2. Each of first bottom resistor 900b1 and second bottom resistor 900b2 is connected at their respective second sides to the midpoint 774 between the switches.

Thus, the gate drive circuit may also comprise the first comparator 800, the gate drive circuit 704 being configured for a magnitude of first voltage signals input to the first inverting input 804 and the first non-inverting input 802 to be scaled using a first voltage divider circuit 900.

As a further option, an additional voltage margin can be added to the first non-inverting input 802 of the first comparator 800 to increase the resilience of zero-crossing comparison, as shown in FIG. 9. Note in this case the first comparator 800 is referenced to the same source Vs of the top switch 710, which eliminates the need of a level shifter. In one example, the two halves of the voltage divider circuit 900 can be identical, the top resistors 900a1, 900a2 are of 100 kilo-Ohm and the two bottom resistors 900b1, 900b2 are of 1 kilo-Ohm. In this case, the switch 764 is not turned on at exact zero voltage, but at a voltage equal to approximately the supply voltage for the comparators and gate drivers, normally around 5V.

Further, an additional ramping capacitor 1000 can be connected in shunt to one of the top resistors, 900a1, 900a2, in this example, second top resistor 900a2 in the voltage divider 900 of the first non-inverting input 802 of the first comparator 800 as shown in FIG. 10. This will force the circuit running non-ZVS-turn-on when the circuit initially starts and the AC current in the resonant tank (load 702, when comprising a capacitor Cx) is building up. The circuit will take an interval to run into ZVS-turn-on. Further, at high frequency operation, the voltage divider circuit 900 will need additional compensation capacitors.

As such, gate drive circuit 704 may further comprise a first ramping capacitor 1000 connected in shunt to a second upper resistor 900a2 in the first voltage divider circuit 900 of the first non-inverting input 802.

### Condition-2: For ZVS Turn-Off of the Top Switch:

This condition two logic block 728 outputs a high logic level on condition two logic block output 734 when the current flowing in the direction from the mid-point 774 between the first and second power switches 764, 770 to the DC sink (ground or the supply voltage rail Vs) has a positive time-derivative, and vice versa. In other words, it is triggered by

$$\frac{{di}_{L}}{dt} > 0 ,$$

as shown in FIG. 7. A truth table for Condition two logic block 728 is given in Table II.

TABLE II
Truth table for Condition-2

| Condition | Output |
|---|---|
| $\frac{{di}_{L}}{dt} > 0$ | H |
| $\frac{{di}_{L}}{dt} \leq 0$ | L |

To get the time-derivative of the current in the inductor Lx, it can be simply detecting the voltage across the inductor element or applying a differentiator over the current signal.

### Example Implementations

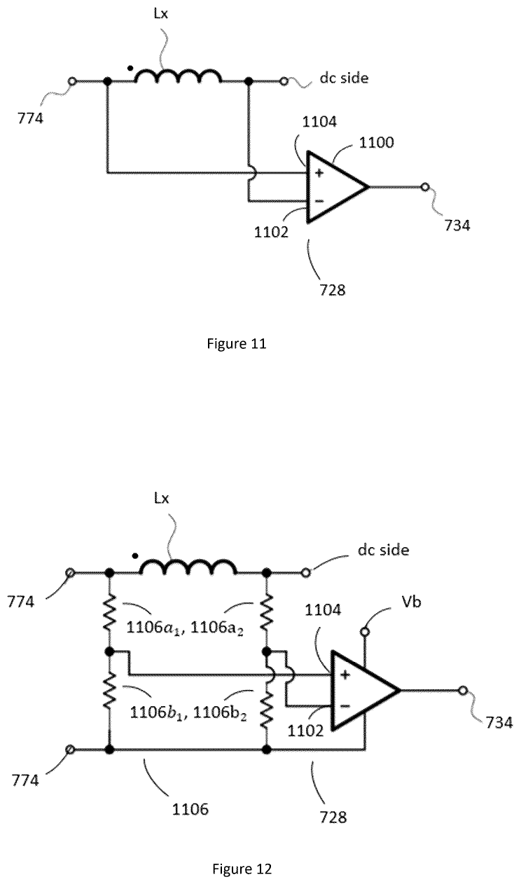

This condition two logic block 728 can be implemented by a comparator circuit having second comparator 1100 which has second comparator second inverting input 1102, second comparator second non-inverting input 1104 and outputting condition two logic block output signal 736 on condition two logic block output 734. The second comparator second non-inverting input 1104 is connected to the dotted side of the inductor Lx and the second comparator second inverting input 1102 is connected to the other end of the inductor Lx, as shown in FIG. 11. The dotted end of the inductor is normally connected to the mid-point between the two switches 744 in the half bridge power inverter leg 700 (the switching node), but there may be additional components in between. The other end is normally connected to DC rails such as the supply voltage rail or the ground through capacitors (the DC side). It will also work with a relatively smaller resistance (resistive load) in series with the inductor or if the load is inductively coupled to the inductor.

Therefore, gate drive circuit 704 is configured for the second gate drive control signal 736 to be a second output signal of a second comparator 1100 having a second inverting input 1102 connected to a DC output side of an inductor Lx of the inductive-resistive load 702 and a second non-inverting input 1104 connected to the midpoint 774 between the first power switch and the second power switch, and configured for the second gate drive control signal 736 to indicate when the slope of the load current in the inductive-resistive load 702 is positive.

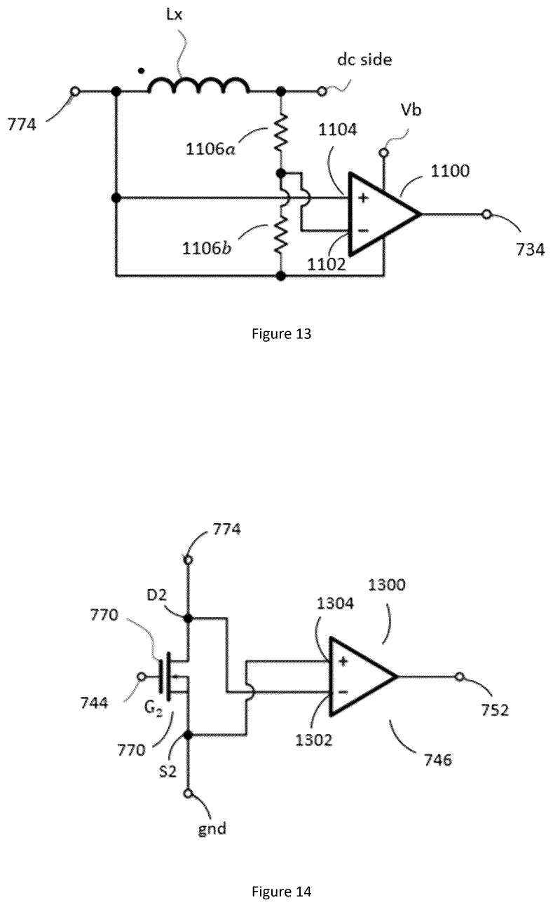

In practice, additional voltage divider circuits shall be used with the reference to the source of the top switch to scale down the input signals within the acceptable range of the comparator, as shown in FIG. 12. A second voltage divider circuit 1100 comprising top resistors 1106a1, 1106a2 and bottom resistors 1106b1, 1106b2 may be used to scale the input signals from the midpoint 744 between the switches and the DC side of the load inductor Lx within the acceptable range of the second comparator 1100. In the example of FIG. 12, first top resistor 1106a1 is connected on a first side thereof to the dotted side of the inductor and the midpoint 774 between the switches and, on a second side thereof, to the first bottom resistor 1106b1, at a first side of that, and to the second comparator second non-inverting input 1104. Second top resistor 1106a2 is connected at a first side thereof to DC side node and at a second side thereof to the second comparator second inverting input 1102 and to a first side of second bottom resistor 1106b2. Each of first bottom resistor 1106b1 and second bottom resistor 1106b2 is connected at their respective second sides to the midpoint 774 between the switches. In the example connection in FIG. 7, the non-inverting input of the comparator can be directly connected to the dotted side of the inductor, as shown in FIG. 13.

The second comparator 1100 and associated components may be part of the gate drive circuit, in which case the gate drive circuit 704 is configured for a magnitude of voltage signals input to the second inverting input 1102 and, optionally, the second non-inverting input 1104, to be scaled using a second voltage divider circuit 1106. It will also be appreciated the gate drive circuit and the second comparator may be part of the power inverter.

When both Condition-1 and Condition-2 are satisfied, first AND gate 710 outputs a logical high output signal 716 which in turn feeds into first power switch first gate terminal G1 and first power switch 764 (top switch S₁) in the inverter leg 700 for a half-bridge power inverter (FIG. 7) is turned on under zero-voltage conditions. That is, the gate drive circuit 704 is configured to generate a first gate drive control signal 726 indicative of the conductive condition of the first reverse conduction channel 766; to generate a second gate drive control signal 736 indicative of the slope of load current in the inductive-resistive load 702; and to switch the first power switch 764 to a conductive state when the first reverse conduction channel 766 is in a conductive condition and when the slope of load current in the inductive-resistive load 702 is positive.

For zero-voltage turn-on of the second (bottom) power switch 770 (S₂) in the inverter leg 700, two conditions are needed as in the following discussion.

### Condition-3: For ZVS Turn-on of the Bottom Switch:

Condition-3 logic block 746 outputs a high logic level on condition one logic block output 752 when the equivalent reverse conduction channel (in this example, the anti-parallel body-diode 772) of the second power switch 770 is forced on by the reverse current from the ground to the mid-point 774, and vice versa. In other words, it is triggered by vₛ₂≤0 as shown in FIG. 7. A truth table for Condition-3 is given in Table III.

TABLE III
Truth table for Condition-3

| Condition | Output |
|---|---|
| v_{S2} ≤ 0 | H |
| v_{S2} > 0 | L |

Thus, it will be appreciated that the gate drive circuit 704 is configured for the third gate drive control signal 754 to indicate when a second reverse conduction channel voltage Vₛ₂ is less than or equal to zero.

### Example Implementations

Referring to FIG. 14, this condition three logic block 714 can be implemented by a third comparator circuit having a third comparator 1300 with third inverting input 1302 connected to the mid-point 774 between the two switches 764, 770 in the same inverter leg 700, and third non-inverting input 1304 connected to ground. As such, comparator 1300 is measuring the voltage Vₛ₂ developed across the second power switch 770, the second antiparallel diode 772 and the second power switch parasitic capacitance 773.

That is, the the third gate drive control signal 754 is a third output signal of a third comparator 1300 having a third inverting input 1302 connected to the midpoint 774 between the first and second power switches and a third non-inverting input 1304 connected to ground.

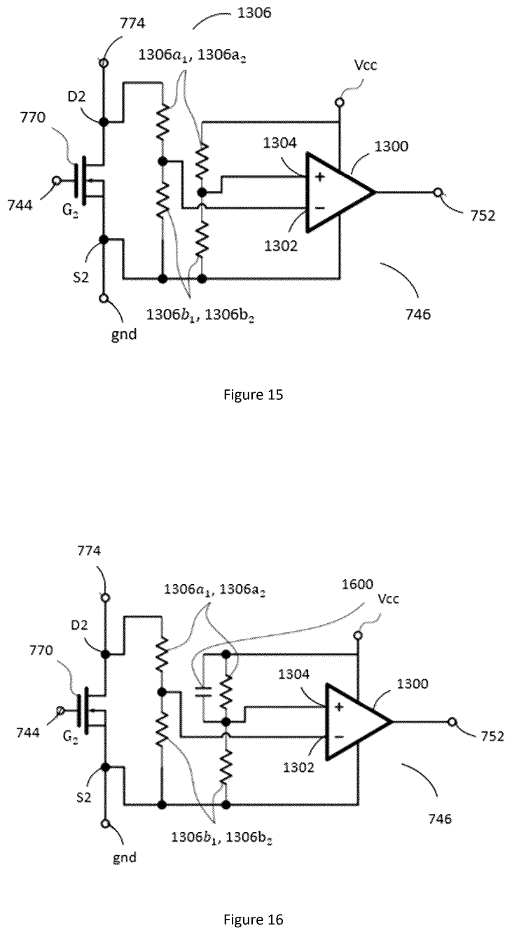

Variations of implementations similar to the condition one logic block 718 as described above can be applied to condition three logic block 746 as well. For example, a third voltage divider 1306 may be used as shown in FIG. 15. Third voltage divider circuit 1306 comprises top resistors 1306a1, 1306a2 and bottom resistors 1306b1, 1306b2 which may be used to scale the input signals from the midpoint 774 and from ground within the acceptable range of the third comparator 1300. In the example of FIG. 15, first top resistor 1306a1 is connected on a first side thereof to the midpoint 774 between the switches and the second power switch second drain terminal D2 and, on the second side thereof, to the first bottom resistor 1306b1, at a first side of that, and to the third inverting input 1302 of third comparator 1300. Second top resistor 1306a2 is connected at a first side thereof to the DC supply voltage rail for the control electronics (such as the logic circuits, comparator and op-amp circuits) V_{cc}. and at a second side thereof to third non-inverting input 1304 of the third comparator 1300 and to a first side of second bottom resistor 1306b2. Each of first bottom resistor 1306b1 and second bottom resistor 1306b2 is connected at their respective second sides to ground.

The gate drive circuit may also comprise the third comparator 1300 and be configured for a magnitude of third voltage signals input to the third inverting input 1302 and the third non-inverting input 1304 to be scaled using a third voltage divider circuit 1306. Further, a third ramping capacitor 1600 may be connected in shunt to a second upper resistor 1306a2 in the third voltage divider 1306 of the third non-inverting input 1304.

In this example, both upper resistors can be 100 kOhm, and both lower resistors can be 1 kOhm. As in FIG. 10, a ramping capacitor-here, third ramping capacitor 1600—can be connected in parallel with second top resistor 1306a2 as shown in FIG. 16. One exemplary third ramping capacitor 1600 has a capacitance of 100 pF.

### Condition-4: For ZVS Turn-Off of the Bottom Switch:

This condition four logic block 756 outputs a high logic level on condition four logic block output 762 when the current flowing in the direction from the mid-point 774 between the first and second power switches 764, 770 to the DC sink (ground or the supply voltage rail) has a negative time-derivative, and vice versa. In other words, it is triggered by

$$\frac{{di}_{L}}{dt} < 0 ,$$

as shown in FIG. 7. A truth table for Condition four logic block 756 is given in Table IV.

TABLE IV
Truth table for Condition-4

| Condition | Output |
|---|---|
| $\frac{{di}_{L}}{dt} < 0$ | H |
| $\frac{{di}_{L}}{dt} \geq 0$ | L |

To get the time-derivative of the current in the inductor Lx, it can be simply detecting the voltage across the inductor element or applying a differentiator over the current signal. Note that this may simply re-use the second gate drive signal 736 or a fourth gate drive signal 763 replicating the state of the second gate drive signal may be generated.

Therefore, gate drive circuit 704 is configured for the fourth gate drive control signal 763 to be a fourth output signal of a fourth comparator 1700 having a fourth inverting input 1702 connected to the midpoint 774 between the first power switch and the second power switch and a fourth non-inverting input 1704 connected to a DC output side of the inductor Lx of the inductive-resistive load 702 and configured for the fourth gate drive control signal 763 to indicate when the slope of the load current is negative. Also, the gate drive circuit may comprise the fourth comparator 1700 and be configured for a magnitude of voltage signals input to the fourth inverting input 1702 and, optionally, the fourth non-inverting input 1704, to be scaled using a fourth voltage divider circuit 1706.

### Example Implementations

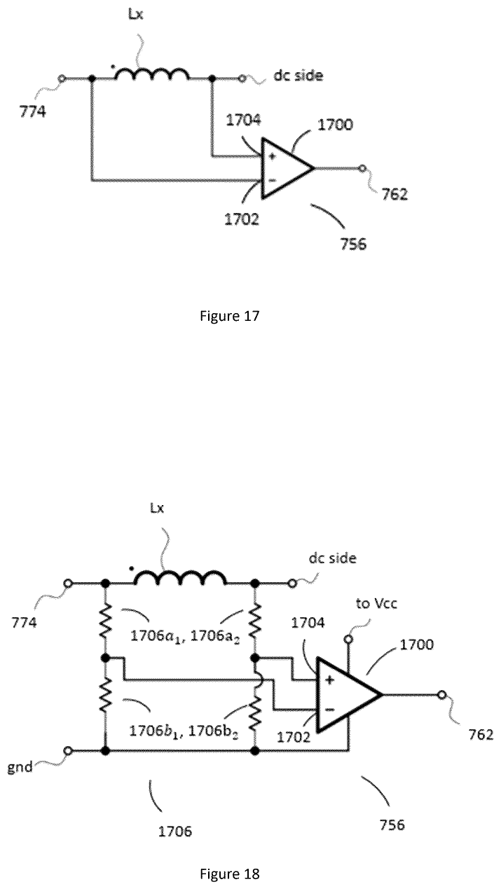

This condition four logic block 756 can be implemented by a comparator circuit having a fourth comparator 1700 with fourth comparator fourth inverting input 1702 connected to the dotted side of the inductor which is connected to the midpoint 774 between the first and second power switches 764, 770 but there may be other components in between. Fourth comparator fourth non-inverting input 1704 is connected to the other end of the inductor, as shown in FIG. 17. Variations of implementations similar to condition two logic block 728 described above can be applied to condition four logic block 756 as well.

For instance, and as shown in FIG. 18, fourth voltage divider circuit 1706 comprising top resistors 1706a1, 1706a2 and bottom resistors 1706b1, 1706b2 may be used to scale the input signals from the midpoint 744 between the switches and the DC side of the load inductor Lx within the acceptable range of the fourth comparator 1700. In the example of FIG. 18, first top resistor 1706a1 is connected on a first side thereof to the dotted side of the inductor and the midpoint 774 between the switches and, on a second side thereof, to the first bottom resistor 1706b1, at a first side of that, and to the fourth comparator fourth inverting input 1702. Second top resistor 1706a2 is connected at a first side thereof to DC side node and at a second side thereof to the fourth comparator fourth non-inverting input 1704 and to a first side of second bottom resistor 1706b2. Each of first bottom resistor 1706b1 and second bottom resistor 1706b2 is connected at their respective second sides to ground.

In one example, both upper resistors can be 100 kOhm and both lower resistors can be 1 kOhm.

When both Condition-3 and Condition-4 are satisfied, second AND gate 738 outputs a logical high output signal 744 which in turn feeds into second power switch second gate terminal G2 and second power switch 770 (bottom power switch S₂) in the inverter leg 700 of the half-bridge power inverter is turned on under zero-voltage conditions. That is, gate drive circuit 704 is configured to generate a third gate drive control signal 754 indicative of the conductive condition of the second reverse conduction channel 772; to generate the second gate drive input signal 736 or a fourth gate drive input 763 signal indicative of the slope of load current in the inductive-resistive load 702; and to switch the second power switch 770 to a conductive state when the second reverse conduction channel 772 is in a conductive condition and when the slope of load current in the inductive-resistive load 702 is negative.

FIG. 19 provides an example of the bootstrap circuit that generates the supply rail Vs for upper gate drive circuits. When the first (top) and (bottom) switches 764, 770 are operating complementarily, the bootstrap supply rail Vb will reserve a voltage close to the Vs value, with reference to the floating switching node.

Thus it will be appreciated that FIG. 7 illustrates a gate drive circuit 704 for a power inverter leg 700 in a power inverter, the power inverter leg 700 comprising a first power switch 764 with a first reverse conduction channel 766 and a second power switch 770 with a second reverse conduction channel 772, the power inverter leg 700 being configured to drive an inductive-resistive load 702, the gate drive circuit 704 comprising: a first gate drive sub-circuit 706 for controlling switching of the first power switch 764; a second gate drive sub-circuit 708 for controlling switching of the second power switch 770; wherein the gate drive circuit 704 is configured to control switching of the first and second power switches 764, 770 in a complementary manner, and based on gate drive input signals 722, 732, 750, 760 to the first and second gate drive sub-circuits 706, 708, the gate drive input signals being 722, 732, 750, 760 indicative of conduction conditions of the first and second reverse conduction channels 766, 772 and a slope of load current in the inductive-resistive load 702.

A power inverter comprising the gate drive circuit 704 described above is also disclosed.

A corresponding method of operation also been described. Thus, there is disclosed a method of operating a gate drive circuit 704 for a power inverter leg 700 in a power inverter, the power inverter leg 700 comprising a first power switch 764 with a first reverse conduction channel 766 and a second power switch 770 with a second reverse conduction channel 772, the power inverter leg 700 driving an inductive-resistive load 702, the gate drive circuit 704 comprising: a first gate drive sub-circuit 706 for controlling switching of the first power switch 764; a second gate drive sub-circuit 708 for controlling switching of the second power switch 770; the method comprising: operating the gate drive circuit 704 to control switching of the first and second power switches 764, 770 in a complementary manner, and based on gate drive input signals 722, 732, 750, 760 to the first and second gate drive sub-circuits 706, 708, the gate drive input signals 722, 732, 750, 760 being indicative of conduction conditions of the first and second reverse conduction channels 766, 772 and a slope of load current in the inductive-resistive load 702.

A practical example will now be discussed with reference to FIG. 20.
Where V_{sw} is the voltage at the midpoint between the first and second power switches (point 774 in FIG. 7), condition-1 is satisfied when V_{sw}≥V_{S} (based on the detection of the reverse voltage of the power switch or the voltage across the antiparallel diode of the power switch);
Condition-2 is satisfied when V_{sw}≥Vₙ (based on the detection of the voltages on the two sides of the inductor in the load branch).
Condition-3 is satisfied when gnd≥V_{sw} (based on the detection of the reverse voltage of the bottom power switch);
Condition-4 is satisfied when V_{sw}≤Vₙ (based on the voltage measurements on the two sides of the inductor in the load branch).

In the practical implementation, four comparators are used to detect the four conditions. In FIG. 20, V_{sw} and V_{S} are fed to the positive input and negative input of the comparator U₁, respectively. When the antiparallel diode D_{S1} of S₁ is turned on by the load current, V_{sw}>V_{S}. When Condition-1 is met, the output of U₁ is high. The signals V_{sw} and Vₙ are fed to the positive and negative inputs of the second comparator U₂. Their voltage difference represents the voltage on two sides of the inductor, which in turn, represents the slope of the load current. When V_{sw}>Vₙ, Condition-2 is met and the output of the comparator U₂ become high. The outputs of U₁ and U₂ are fed to the input terminals of an AND logic gate A₁. When both input signals are high, the output of the A₁ becomes high, indicating that S₁ is switched on. Similar arguments apply to the gate drive for the bottom switch S₂. Here, the voltages gnd and V_{sw} are fed to the positive and negative input terminals of the third comparator U₃, respectively. When gnd>V_{sw}, it indicates that the body diode D_{S2} of S₂ is conducting. Condition-3 is met and the output of U₃ becomes high. Voltages Vₙ and V_{sw} are fed to the positive and negative input terminals of the fourth comparator U4, respectively, to detect the slope of the load current. When V_{sw}<Vₙ, the load current has a negative slope and Condition-4 is met and the output of U₄ goes high. The outputs of U₃ and U₄ are fed to the input terminals of an AND gate A₂. When both Condition-3 and Condition-4 are met, the output of A₂ goes high, indicating that S₂ is switched on.

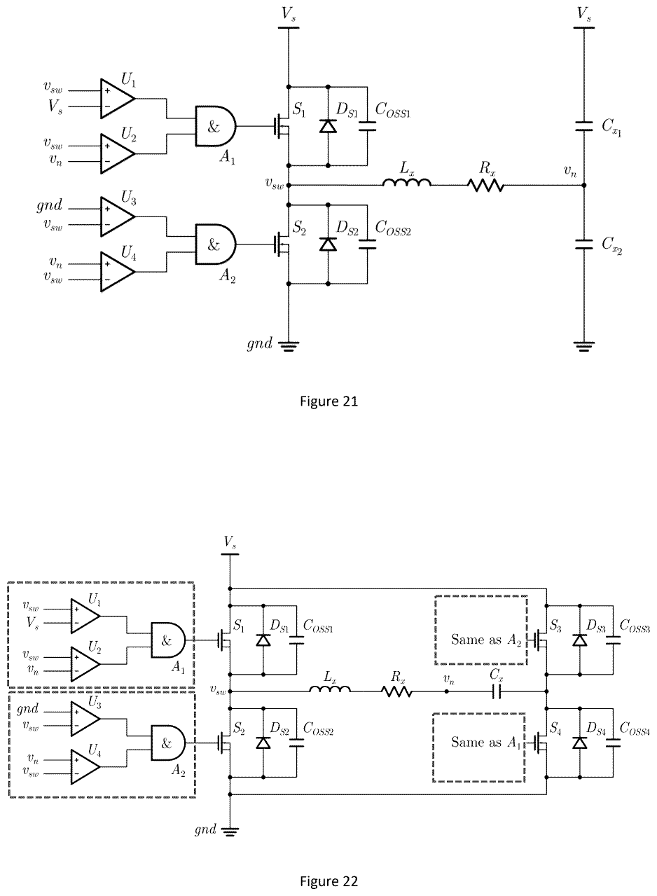

The proposed high-frequency gate drive system can be applied to half-bridge power inverter as shown in FIG. 21. It should be noted that, from a circuit theory point of view, the power circuit in FIG. 21 is equivalent to that in FIG. 20 where Cₓ is the sum of Cₓ₁ and Cₓ₂.

The techniques disclosed above in respect of a single power inverter leg—a half-bridge power inverter—are extendable to cover operation in full-bridge power inverters too, as discussed with reference to FIG. 22. In a full-bridge power inverter, S₁ and S₄ form a diagonal pair of power switches. They are turned on and off at the same time. For this reason, their gate drive circuits are identical. Similarly, S₂ and S₃ form another diagonal pair of power switches. They should have the same switching signals and therefore the same gate drive circuit and control. The logic controls of the top and bottom switches (S₃ and S₄) in the second inverter leg (on the right-hand side) of the full-bridge power inverter are therefore opposite to those of the top and bottom switches (S₁ and S₄) in the first inverter leg on the left-hand side of the full-bridge power inverter.

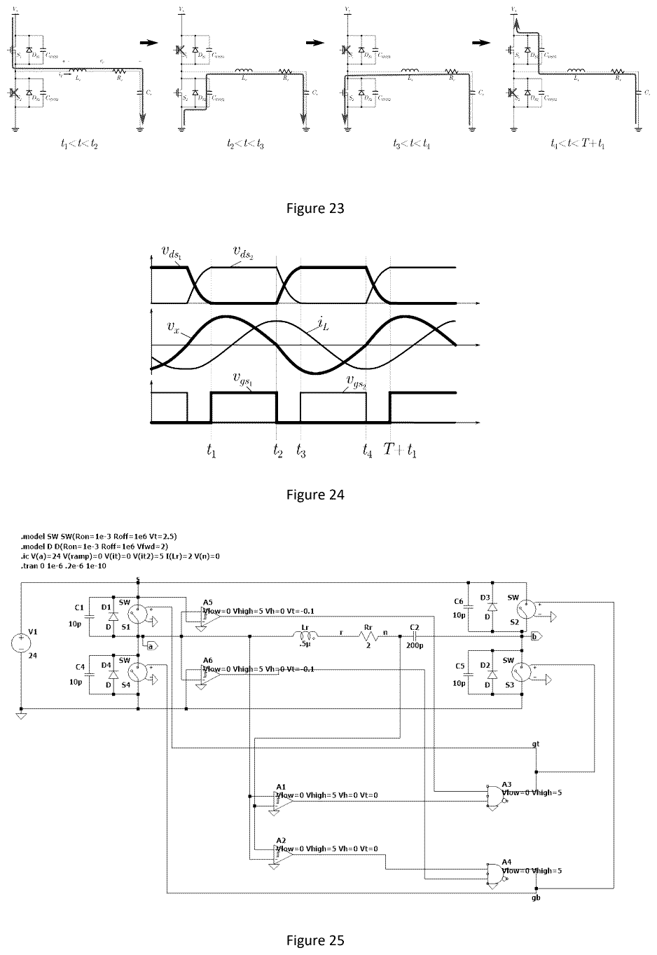

The operating state diagrams in FIG. 23 and the circuit waveforms in FIG. 24 are used to illustrate the operation of the half-bridge power inverter. The operations are described in a stage-by-stage manner in Table V. As the switches are guaranteed to have ZVS, the total power losses on the switches are negligible.

TABLE V
Descriptions of the gate drive control at different time intervals

| Times/Intervals | U₁ | U₂ | S₁ | U₃ | U₄ | S₂ | Actions |
|---|---|---|---|---|---|---|---|
| t < t₁ | L | H | OFF | L | L | OFF | i_{L} remains negative, S₂ is OFF |
| t = t₁ | H | H | ON | L | L | OFF | C_{OSS1} is fully discharged, D_{S1} is |
| | | | | | | | in forward-bias, and v_{ds1} = 0. |
| | | | | | | | U₁ outputs HIGH (v_{sw} > V_{S} as |
| | | | | | | | D_{S1} in forward-bias), U₂ |
| | | | | | | | outputs HIGH (v_{sw} > vₙ, |
| | | | | | | | guaranteed by the previous |
| | | | | | | | operation). S₁ is turned on. |
| t₁ < t < t₂ | H | H | ON | L | L | OFF | S₁ remains ON. i_{L} continues |
| | | | | | | | increasing (v_{sw} > vₙ), until |
| | | | | | | | reaching the peak value. |
| t = t₂ | H | L | OFF | L | H | OFF | $\begin{matrix}{i}_{L} starts to decrease , and \frac{{di}_{L}}{dt} < 0 , \\ {v}_{sw} < {v}_{n} , {U}_{2} outputs LOW ,\end{matrix}$ |
| | | | | | | | A₁ outputs LOW and S₁ is |
| | | | | | | | turned off. |
| t₂ < t < t₃ | L | L | OFF | L | H | OFF | i_{L} continues flowing and |
| | | | | | | | charges up C_{OSS1} and |
| | | | | | | | discharges C_{OSS2}. |
| t = t₃ | L | L | OFF | H | H | ON | C_{OSS2} is fully discharged, D_{S2} is |
| | | | | | | | in forward-bias, and v_{ds2} = 0. |
| | | | | | | | U₃ outputs HIGH (gnd < v_{sw} |
| | | | | | | | as D_{S2} in forward-bias), U₄ |
| | | | | | | | outputs HIGH (v_{sw} < vₙ, |
| | | | | | | | guaranteed by the previous |
| | | | | | | | operation). S₂ is turned on. |
| t₃ < t < t₄ | L | L | OFF | H | H | ON | S₂ remains ON. i_{L} continues |
| | | | | | | | decreasing (v_{sw} < vₙ), until |
| | | | | | | | reaching the negative peak |
| | | | | | | | value. |
| t = t₄ | L | H | OFF | H | L | OFF | $\begin{matrix}{i}_{L} starts to increase , and \frac{{di}_{L}}{dt} > 0 , \\ {v}_{sw} > {v}_{n} , {U}_{4} outputs LOW ,\end{matrix}$ |
| | | | | | | | A₂ outputs LOW and S₂ is |
| | | | | | | | turned off. |
| t₄ < t < T + t₁ | L | H | OFF | L | L | OFF | i_{L} continues flowing and |
| | | | | | | | charges up C_{OSS2} and |
| | | | | | | | discharges C_{OSS1}. |

As explained above, the gate signals are completely self-triggered by the circuit itself. The operating frequency is determined by the loaded resonant frequency of the inductive-capacitive-resistive (LCR) circuit branch in the example of FIG. 7. If the capacitor Cx is small and has the same order of magnitude of the switch's output capacitance C_{OSS}, C_{OSS} will influence the loaded resonant frequency. However, there are several ways to control the output power.

The first method for controlling the output power is by varying the dc-link voltage Vₛ of the power inverter. This can be achieved by having a front-end power converter that can vary its dc output voltage as the dc-link voltage VS for the power inverter using the proposed self-triggered gate drive system.

A second method for controlling the output power is to have an equivalent load with self-regulation on power consumption. The equivalent load Rx in previous explanation of the simplified circuit operation can represent a power converter with closed-loop power/voltage regulation for feeding an electric load. This power converter for feeding the electric load is termed the load-power-converter here. The resistance Rx is equivalent to the input resistance of the load-power-converter that can be controlled by the duty-cycle control for the load-power-converter operation. In this way, the value of the equivalent Rx in the equivalent electric circuit branch will change dynamically according to the power consumption.

A third method for controlling the output power is to use a switchable inductor so that the value of the equivalent impedance Lₓ can be varied.

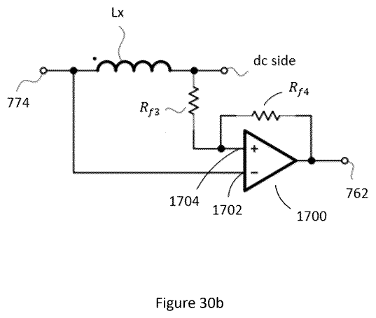

A fourth method for controlling the output power is to add hysteresis control to the comparators for Condition-2 and Condition-4 so that the turn-off time can be postponed. This will change the phase shift between the voltage and current on the load and affect the real power output. Referring to FIG. 30a, a first implementation of this fourth method is illustrated. It will be noted that FIG. 30a illustrates a further variant of the circuit of FIG. 11. In this variant, a first control resistor R_{f1} is connected on a first end at the midpoint 744 between the switches 764, 770 (and also at the dotted end of the Inductor Lₓ) and at a second end to second comparator second non-inverting input 1104. Second control resistor R_{f2} is connected on a first end at condition two logic block output 734 and at a second end to second comparator second non-inverting input 1104.

Referring then to FIG. 30b, a second implementation of this fourth method is illustrated. It will be noted that FIG. 30b illustrates a further variant of the circuit of FIG. 17. In this variant, a third control resistor R_{f3} is connected on a first end at the dc side of the inductor Lₓ and at a second end to fourth comparator fourth non-inverting input 1704. Fourth control resistor R_{f4} is connected on a first end at condition four logic block output 762 and at a second end to fourth comparator fourth non-inverting input 1704.

With the addition of these control resistors, a delay in the toggle action on condition two logic block output 734 and condition four logic block output 762 may be realised. This allows adjustment of the turn off time of the switches, and allows continuous current flow for an extra period of time. Therefore, these resistors modify phase shift(s) between the load (output) voltage and current.

A fifth method for controlling the output power is to replace the Condition-2 and Condition-4 blocks by timer circuits and explicitly controlling the turn-on times of both switches. The timers can be implemented using any known methods. The timers can be started by the corresponding condition block outputs: For Condition-2 timer it is started by Condition-1 output, for Condition-4 timer it is started by Condition-3 output. Like the gate drive circuits, the timer circuit for the upper switch also needs to be referenced to the floating ground of the switching node. The timers can be set with fixed values or externally controlled.

### Verification of the Invention

The proposed gate drive system is demonstrated in a full-bridge power inverter simulation. The circuit diagram is shown in FIG. 25. The dc-link voltage of the power inverter is set at 24V. The load parameters are Lx=0.5 ρH, Cx=200 pF and Rx=2 Ohm. The output capacitance of the power switches is 10 pF. The circuit operates at 17.83 MHz.

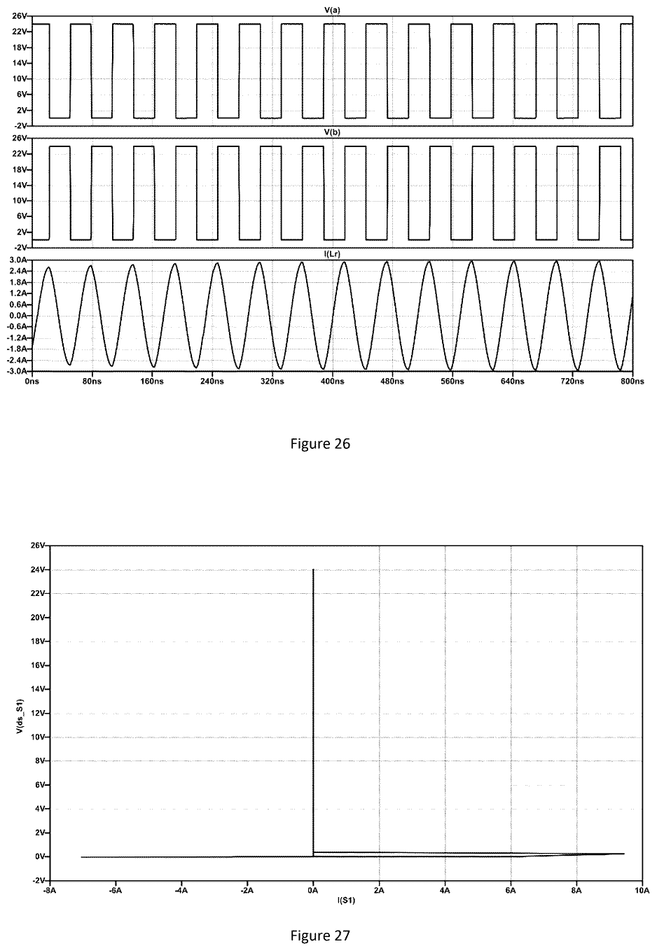

FIG. 26 shows the simulated time-domain waveforms of the inductor current and the mid-point voltages of the inverter legs. The switching trajectory (i.e. the trace of instantaneous voltage and current operating point) of the power switch is shown in FIG. 27, in which the Y-axis is the switch voltage and the X-axis is the switch current. The switching trajectory moves close to and along the zero-voltage and zero-current lines. This confirms that soft switching can be achieved with the use of the proposed gate drive system.

In this design, the gate signal for the top switch (first power switch) is completely generated from a floating circuit referenced to the switching node, and therefore there is no need for an isolated gate drive, and the total propagation delay has been reduced to a minimum. With the current state-of-the-art components, operations at 13.56 MHz or even higher are achievable with excellent performance.

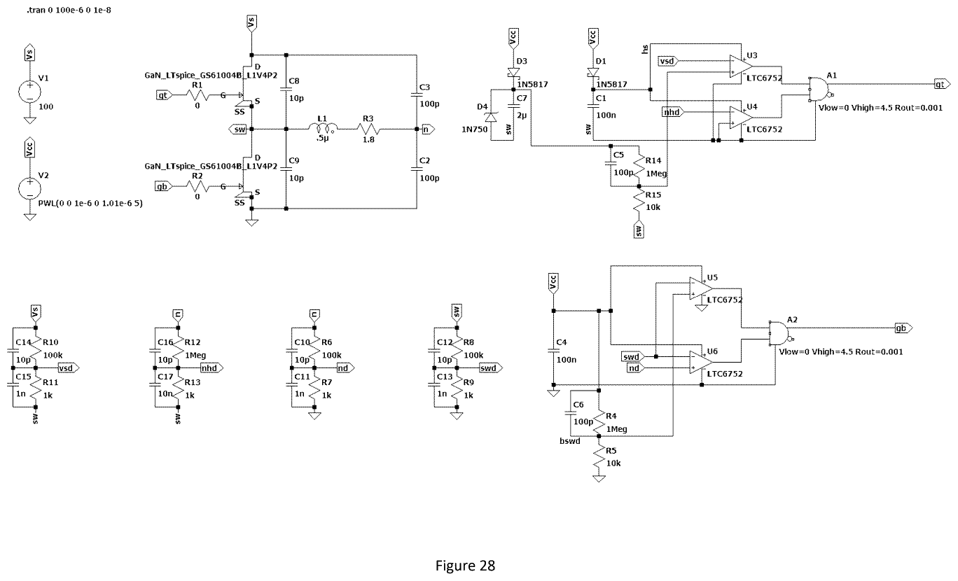

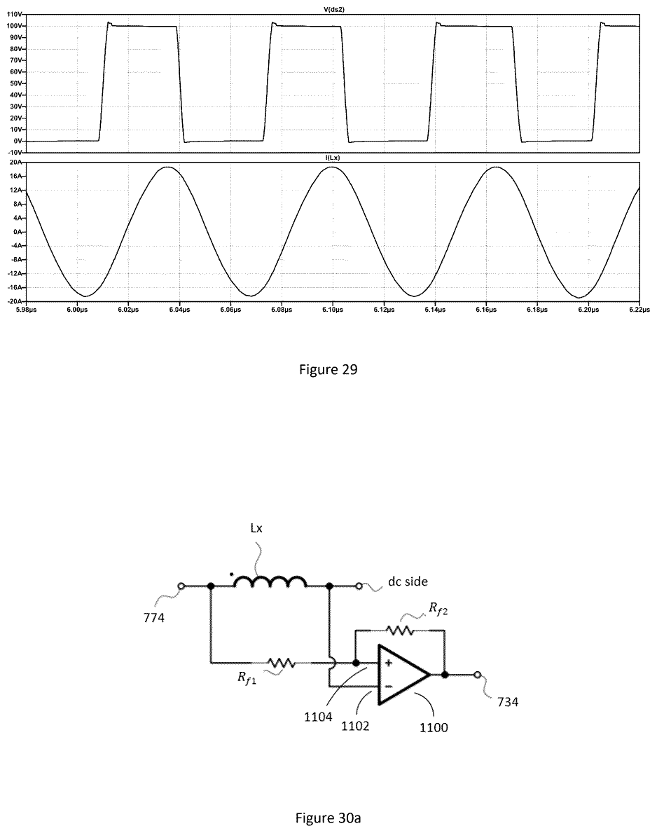

Another example shows a circuit simulation using real component models. The load comprises an inductance of 0.5 uH, a load resistor of 1.8 Ohm and a total compensation capacitance of 200 pF. The switch model used is GS61004B, and an additional 20 pF capacitance is added to the switching node, mocking the parasitic stray capacitance of the PCB traces. The arrangements of the bootstrap circuits and the comparator arrangement can be found in FIG. 28. Notice that there is an additional bootstrap circuit for generating a stable reference voltage signal in the Condition-1 implementation, minimising the voltage ripples due to the power consumptions by the top-side comparators and the AND-gate. The circuit operates at 15.57 MHz and outputs 313.9 W to the resistive load. Simulated waveforms of the inductor current and the mid-point voltages of the power inverter legs are shown in FIG. 29. The power losses on the top and bottom switches are 1.76 W and 1.44 W respectively. The overall circuit achieves an overall efficiency of over 97%.

In practice, an ultra-fast AND gate driver with high current capability, such as the 74LVC1G series, should be selected for the proposed gate drive system. The average propagation latency of such an AND gate is less than 3 ns. The AND gate driver is able to drive a 50 pF load (such as the gate capacitance of a power switch) within 2.5 ns. For future high-power power switch with a relatively large gate-source capacitance, a buffer driver can be added between the AND gate output and the gate of the power switch if necessary.

In view of the discussion herein, it will be appreciated the current application discloses the following concepts.

1. A self-triggered gate drive system comprising two gate drive circuits for driving the top and bottom power switches of a power inverter leg in a complementary manner under soft-switching condition to generate a high-frequency ac output voltage from an input dc voltage source, whereas the inputs of the gate drive system are derived from the conduction conditions of the antiparallel diodes (or other reverse conduction channels) of the power switches and the slope of the load current.

2. A gate drive system of concept 1, whereas the inputs of the gate drive system include the reverse voltages of the power switches in the inverter leg and the polarity of the slope of the load current.

3. A gate drive system of concept 2, whereas the slope of the load current is obtained either directly by a current sensor with a differentiator or indirectly by measuring the voltages on two sides of an inductor in the load branch of the power inverter.

4. A gate drive system of concept 1, whereas the inputs of the gate drive system include (1) the dc-link voltage of the power inverter (Vₛ), (2) the voltage between the two power switches (V_{sw}) in the same inverter leg, (3) a reference voltage (gnd) and (4) a voltage on one side the inductor (Vₙ) in the load branch of the power inverter.

5. The gate drive system of concept 1 comprises two gate drive circuits, one for the top power switch and the other for the bottom power switch of the inverter leg with a totem-pole arrangement.

6. Each of the two gate drive circuits in the gate drive system of concept 1 comprises at least two comparators and one AND logic gate, where the output of the logic gate determines the switching state of the power switch.

7. The AND gates of concept 6 are preferably the ultra-fast type and have high-current driving capability.

8. For high-power power switch with relatively large gate capacitance, a buffer driver can be added between the output of the AND gate of concept 6 and the gate of the power switch if such arrangement can speed up the turn-on and turn-off processes of the power switch.

9. The gating signal feeding the gate of the power switch of the system in concept 1 comprising a voltage divider circuit comprising one or more of resistors, capacitors, inductors and diodes for linearly scaling down the voltage at high frequency ac conditions for high voltage applications.

10. The voltage between the two power switches (V_{sw}) in one inverter leg of concept 1 is used as input to all of the four comparators of two gate drive circuits in the same inverter leg.

11. The gate drive system of concept 1 can be extended to a full-bridge power inverter comprising two inverter legs sharing the same dc-link voltage and ground, where the gate drive logic control and circuits of the top power switch and bottom power switch in the first inverter leg are identical to those of the bottom power switch and top power switch in the second inverter leg, respectively.

12. The self-oscillatory operating frequency of the power inverter using the gate drive system in concept 1 is determined by the loaded resonant frequency of the inductive-capacitive-resistive load branch.

13. A control method for the gate drive system of a power inverter leg in concept 1, where switching action of the top power switch is determined by two conditions, namely Conditon-1 and Condition-2, and that of the bottom switch is determined by two conditions, namely Condition-3 and Conditon-4; whereas the four conditions are defined as:

Condition-1: When the voltage across the top switch (Vₛ₁)≤0, the logic output is High. When (Vₛ₁)>0, the logic output is Low.

Condition-2: Assuming that the current entering the load from the mid-point of the inverter leg (i.e. the connection point between the top and bottom switches) is defined as the positive direction, when the rate of change of the load current (d_{iL}/dt)>0, the logic output is High; when d_{iL}/dt>0, the output logic is Low.

Condition-3: When the voltage across the bottom switch (Vₛ₂)≤0, the logic output is High. When (Vₛ₂)>0, the logic output is Low.

Condition-4: Assuming that the current entering the load from the mid-point of the inverter leg (i.e. the connection point between the top and bottom switches) is defined as the positive direction, when the rate of change of the load current (d_{iL}/dt)<0, the logic output is High; when d_{iL}/dt≥0, the output logic is Low.

14. A control method for the gate drive system of a power inverter leg in concept 13, where the top power switch is turned on when both Conditon-1 and Condition-2 have logic outputs High, and the bottom switch is turned on when both Condition-3 and Conditon-4 have logic outputs High.

15. A control method to control the output power of the power inverter driven by the self-triggered gate drive system of concept 1 for a half-bridge power inverter or a full-bridge power inverter by controlling the dc-link voltage of the power inverter.

16. A control method to control the output power of the power inverter driven by the self-triggered gate drive system of concept 1 for a half-bridge power inverter or a full-bridge power inverter by using a power converter with voltage or power regulation capability for powering an energy-consuming electric load in the load branch of the power inverter.

17. A control method to control the output power of the power inverter driven by the self-triggered gate drive system of concept 1 for a half-bridge power inverter or a full-bridge power inverter by using a switchable inductor or a switchable capacitor or a combination of both, in order to alter the impedance of the load branch and thus the current and power of the load.

18. A control method to control the output power of the power inverter driven by the self-triggered gate drive system of concept 13 by adding hysteresis control to the comparators for Condition-2 and Condition-4 so that the turn-off time can be postponed in order to change the phase shift between the voltage and current on the load and control the real power output.

19. A control method to control the output power of the power inverter driven by the self-triggered gate drive system of concept 13 by replacing the Condition-2 and Condition-4 gate drive blocks with timer circuits and explicitly controlling the turn-on times of both switches, with the output of the Condition-1 control block starting the timer circuit for the turn-on time of the top switch, the output of the Conditon-2 control block starting the time circuit for the turn-on time of the bottom power switch, and the output power determined by the turn-on period of the controllable timer circuits.

It will be appreciated that the invention has been described by way of example only. Various modifications may be made to the techniques described herein without departing from the spirit and scope of the appended claims. The disclosed techniques comprise techniques which may be provided in a stand-alone manner, or in combination with one another. Therefore, features described with respect to one technique may also be presented in combination with another technique.

1. A gate drive circuit for a power inverter leg in a power inverter, the power inverter leg comprising a first power switch with a first reverse conduction channel and a second power switch with a second reverse conduction channel, the power inverter leg being configured to drive an inductive-resistive load, the gate drive circuit comprising:
a first gate drive sub-circuit for controlling switching of the first power switch;
a second gate drive sub-circuit for controlling switching of the second power switch; wherein
the gate drive circuit is configured to control switching of the first and second power switches in a complementary manner, and based on gate drive control signals of the first and second gate drive sub-circuits, the gate drive control signals being indicative of conduction conditions of the first and second reverse conduction channels and a slope of load current in the inductive-resistive load.

2. The gate drive circuit of claim 1, configured:
to generate a first gate drive control signal indicative of the conductive condition of the first reverse conduction channel;
to generate a second gate drive control signal indicative of the slope of load current in the inductive-resistive load; and
to switch the first power switch to a conductive state when the first reverse conduction channel is in a conductive condition and when the slope of load current in the inductive-resistive load is positive.

3. The gate drive circuit of claim 2, configured for the first gate drive control signal to indicate when a first reverse conduction channel voltage is less than or equal to zero.

4. The gate drive circuit of claim 2, wherein the first gate drive control signal is a first output signal of a first comparator having a first non-inverting input connected to a supply voltage rail and a first inverting input connected to a midpoint between the first power switch and the second power switch.

5. The gate drive circuit of claim 4 further comprising the first comparator, the gate drive circuit being configured for a magnitude of first voltage signals input to the first inverting input and the first non-inverting input to be scaled using a first voltage divider circuit.

6. The gate drive circuit of claim 5, further comprising a first ramping capacitor connected in shunt to a second upper resistor in the first voltage divider circuit of the first non-inverting input.

7. The gate drive circuit of claim 2, wherein the second gate drive control signal is a second output signal of a second comparator having a second inverting input connected to a DC output side of an inductor of the inductive-resistive load and a second non-inverting input connected to the midpoint between the first power switch and the second power switch, and configured for the second gate drive control signal to indicate when the slope of the load current in the inductive-resistive load is positive.

8. The gate drive circuit of claim 7, further comprising the second comparator, the gate drive circuit being configured for a magnitude of voltage signals input to the second inverting input and, optionally, the second non-inverting input, is scaled using a second voltage divider circuit.

9. The gate drive circuit of claim 2, configured:
to generate a third gate drive control signal indicative of the conductive condition of the second reverse conduction channel;
to generate the second gate drive input signal or a fourth gate drive input signal indicative of the slope of load current in the inductive-resistive load; and
to switch the second power switch to a conductive state when the second reverse conduction channel is in a conductive condition and when the slope of load current in the inductive-resistive load is negative.

10. The gate drive circuit of claim 9, configured for the third gate drive control signal to indicate when a second reverse conduction channel voltage is less than or equal to zero.

11. The gate drive circuit of claim 9, wherein the third gate drive control signal is a third output signal of a third comparator having a third inverting input connected to the midpoint between the first and second power switches and a third non-inverting input connected to ground.

12. The gate drive circuit of claim 11 further comprising the third comparator and being configured for a magnitude of third voltage signals input to the third inverting input and the third non-inverting input to be scaled using a third voltage divider circuit.

13. The gate drive circuit of claim 11 further comprising a third ramping capacitor connected in shunt to a third upper resistor in the third voltage divider of the third non-inverting input.

14. The gate drive circuit of claim 9, wherein the fourth gate drive control signal is a fourth output signal of a fourth comparator having a fourth inverting input connected to the midpoint between the first power switch and the second power switch and a fourth non-inverting input connected to a DC output side of the inductor of the inductive-resistive load and configured for the fourth gate drive control signal to indicate when the slope of the load current is negative.

15. The gate drive circuit of claim 14 further comprising the fourth comparator and configured for a magnitude of voltage signals input to the fourth inverting input and, optionally, the fourth non-inverting input, to be scaled using a fourth voltage divider circuit.

16. A power inverter comprising a gate drive circuit of a power inverter leg of the power inverter, the power inverter leg comprising a first power switch with a first reverse conduction channel and a second power switch with a second reverse conduction channel, the power inverter leg being configured to drive an inductive-resistive load, the gate drive circuit comprising:
a first gate drive sub-circuit for controlling switching of the first power switch;
a second gate drive sub-circuit for controlling switching of the second power switch; wherein
the gate drive circuit is configured to control switching of the first and second power switches in a complementary manner, and based on gate drive control signals of the first and second gate drive sub-circuits, the gate drive control signals being indicative of conduction conditions of the first and second reverse conduction channels and a slope of load current in the inductive-resistive load.

17. A method of operating a gate drive circuit for a power inverter leg in a power inverter, the power inverter leg comprising a first power switch with a first reverse conduction channel and a second power switch with a second reverse conduction channel, the power inverter leg driving an inductive-resistive load, the gate drive circuit comprising:
a first gate drive sub-circuit for controlling switching of the first power switch;
a second gate drive sub-circuit for controlling switching of the second power switch; the method comprising:
operating the gate drive circuit to control switching of the first and second power switches in a complementary manner, and based on gate drive input signals to the first and second gate drive sub-circuits, the gate drive input signals being indicative of conduction conditions of the first and second reverse conduction channels and a slope of load current in the inductive-resistive load.
